(19) United States
(12) Patent Application Publication
(10) Pub. No.: US 2013/0255754 A1
(43) Pub. Date: Oct. 3, 2013

(54) PHOTOVOLTAIC DEVICE AND METHOD OF FABRICATING THEREOF

(71) Applicants: Richard Henry Friend, Fulbourn (GB); Neil Clement Greenham, Cambridge (GB); Bruno Ehrler, Cambridge (GB); Brian Walker, Cambridge (GB)

(72) Inventors: Richard Henry Friend, Fulbourn (GB); Neil Clement Greenham, Cambridge (GB); Bruno Ehrler, Cambridge (GB); Brian Walker, Cambridge (GB)

(73) Assignee: CAMBRIDGE ENTERPRISE LIMITED, Cambridge (GB)

(21) Appl. No.: 13/434,648

(22) Filed: Mar. 29, 2012

(51) Int. Cl. H01L 51/46; H01L 51/48; H01L 27/30; B82Y 40/00; B82Y 15/00

(52) U.S. Cl. 136/250; 438/63; 136/263; 257/E51.015; 977/774; 977/948

(57) ABSTRACT

An organic/inorganic hybrid photovoltaic device architecture. In some variations, power conversion efficiencies approach 1%. Some variations include an unexpected order of magnitude improvement of power conversion efficiency approaching 5%. Methods of fabricating a photovoltaic device, including depositing over a first electrode an organic semiconductor layer; depositing over the organic semiconductor layer a cross-linking ligand layer; depositing over the cross-linking ligand layer an inorganic nanocrystal layer; and depositing a second electrode over the inorganic nanocrystal layer.

### BACKGROUND

The present invention relates to hybrid organic/inorganic photovoltaic devices or solar cells comprising an inorganic lead chalcogenide nanocrystal layer adjacent an organic semiconductor layer. Preferred materials include an organic semiconductor capable of singlet fission such as the polyacene pentacene and nanocrystals comprising lead selenium (PbSe) or lead sulfide (PbS).

The desire for photovoltaic device architectures that combine reduced manufacturing costs and adequate power conversion efficiency has motivated research into candidate technologies such as organic solar cells, hybrid organic/inorganic solar cells and fully inorganic nanocrystal solar cells. In particular, the reported efficiency of fully inorganic nanocrystal colloidal quantum dot solar cells, where the photoactive layer consists of solution-processable inorganic semiconductor nanocrystals, has recently made tremendous progress with 5.1% AM1.5 power conversion efficiencies being reported for colloidal quantum dot/transparent conductive oxide solar cells in “Depleted-Heterojunction Colloidal Quantum Dot Solar Cells”; Pattantyus-Abraham and Kramer et al, ACS Nano, 4, no. 6, 3374-3380, (2010).

However, much of the solar energy that reaches the earth's surface lies in the infrared. Although nanocrystals that absorb in this region can be synthesized much of the available energy of the visible and UV photons absorbed by such a device is lost to heat as carriers thermalize to the lowest-energy states. Approaches to overcome this fundamental barrier in nanocrystal solar cells have included multiple exciton generation (MEG), hot carrier collection, and the use of tandem cell architectures.

One approach is presented in “Enhanced photovoltaic performance in nanoimprinted pentacene-PbS nanocrystal hybrid device”; Dissanayake, D et al, Applied Physics Letters, 92, 093308, (2008). Pentacene and PbS nanocrystal bilayer photovoltaic devices are fabricated after the pentacene layer is subjected to a nanoimprinting step using a laser textured silicon stamp. According to Dissanayake et al, the additional processing step of nanoimprinting causes the pentacene film to undergo localized high pressures during nanoimprinting giving rise to increased hole mobilities.

### SUMMARY

According to the present invention, we present an alternative fabrication route and novel resultant device to better utilize the high-energy photons absorbed in an infrared nanocrystal solar cell. As will be understood, in one embodiment of the present invention we present an organic/inorganic hybrid photovoltaic device architecture with power conversion efficiencies approaching 1%. In another embodiment of the present invention we present an inorganic/inorganic hybrid photovoltaic device architecture with an unexpected order of magnitude improvement of power conversion efficiency approaching 5%.

According to a first aspect of the present invention, there is provided a method of fabricating a photovoltaic device comprising: depositing over a first electrode an organic semiconductor layer; depositing over the organic semiconductor layer a cross-linking ligand layer; depositing over the cross-linking ligand layer an inorganic nanocrystal layer comprising lead chalcogenide nanocrystals; and depositing a second electrode over the inorganic nanocrystal layer.

Preferably, the lead chalcogenide nanocrystal is lead selenide or lead sulfide.

Preferably, including depositing over the inorganic nanocrystal layer one or more further inorganic nanocrystal layer(s).

Preferably, including depositing one or more layers comprising a further cross-linking ligand layer over the inorganic nanocrystal layer and over the further cross-linking ligand layer depositing a further inorganic nanocrystal layer.

Preferably, the further inorganic nanocrystal layer(s) comprises lead chalcogenide nanocrystals.

Preferably, the further inorganic nanocrystal layer(s) comprises any one or more of nanocrystals comprising CdSe, CDS, ZnTe, ZnSe. PbS, PbSe, PbTe, HgS, HgSe, HgTe, HgCdTe, CdTe, CZTS, ZnS, CuInS2, CuInGaSe, CuInGaS, Si, InAs, InP, InSb, SnS2, CuS, Fe2S3

Preferably, depositing includes spin-coating, spray coating, inkjet printing, dip coating, spray pyrolysis or screen printing.

Preferably, the organic semiconductor layer comprises a polyacene. More preferably, the polyacene is pentacene.

Preferably, the cross-linking ligand layer comprises benzene-1,3-dithiol. Other cross-linking materials can be selected from ethylene diamine, ethane dithiol, butane dithiol, hydrazine, propane dithiol and hydrogen sulfide.

Preferably, comprising imprinting the organic semiconductor layer prior to depositing over the organic semiconductor layer the cross-linking ligand layer.

Preferably, the first electrode is an anode and the second electrode is a cathode.

According to a second aspect of the present invention, there is provided a photovoltaic device comprising: a first electrode; a second electrode; and located between the first and the second electrode, an organic semiconductor layer and over the organic semiconductor layer at least one cross-linked inorganic nanocrystal layer comprising lead chalcogenide nanocrystals.

Preferably, the lead chalcogenide nanocrystal is lead selenide or lead sulfide.

Preferably, the cross-linked inorganic nanocrystal layer is a cross-linked ligand layer, comprising preferably benzenedithiol.

Preferably, the cross-linked ligand layer comprises benzene-1,3-dithiol. Other cross-linking materials can be selected from ethylene diamine, ethane dithiol, butane dithiol, hydrazine, propane dithiol and hydrogen sulfide.

Preferably, the first electrode is an anode and the organic semiconductor layer is deposited on the anode electrode.

Preferably, the organic semiconductor layer is a polyacence, most preferably pentacene.

Preferably, comprising layers over the inorganic nanocrystal layer, wherein the layers comprise an inorganic nanocrystal layer.

Preferably, comprising one or more stacked layers over the inorganic nanocrystal layer, wherein the stacked layers comprise one or more of a benzenedithiol cross-linked inorganic nanocrystal layer.

Preferably, the cross-linked ligand layer comprises benzene-1,3-dithiol. Other cross-linking materials can be selected from ethylene diamine, ethane dithiol, butane dithiol, hydrazine, propane dithiol and hydrogen sulfide.

Preferably, the further inorganic nanocrystal layer comprises lead chalcogenide nanocrystals.

Preferably, the further inorganic nanocrystal layer comprises CdSe, CDS, ZnTe, ZnSe. PbS, PbSe, PbTe, HgS, HgSe, HgTe, HgCdTe.

The photovoltaic device generates photocurrent through absorption of light in either or both of the organic semiconductor layer and the lead chalcogenide layer. Advantageously, the device utilizes exciton multiplication through singlet fission to triplet exciton pairs. In this way the organic semiconductor layer e.g., pentacence, produces pairs of excitons from higher energy visible spectrum photons and the lead chalcogenide eg. PbS or PbSe produces single excitons from lower energy infra-red photons that allows, in principle, for the device performance to exceed to so-called Shockley Quiesser limit.

### BRIEF DESCRIPTION OF THE DRAWINGS

Embodiments of the invention will now be described, by way of example only, and with reference to the following drawings of which:

FIG. 1 is a device schematic and energy diagram of a pentacene/PbS NCs solar cell according to a first embodiment of the present invention;

FIG. 2 is a refractive index (n) and extinction coefficient (k) of the pentacene and lead sulfide and zinc oxide nanocrystals according to the first embodiment of the present invention;

FIG. 3 is an external quantum efficiency of the device according to the first embodiment of the present invention;

FIG. 4 is external and internal quantum efficiencies for the device according to variants of the first embodiment of the present invention;

FIG. 5 is an absorption spectra of lead selenide (PbSe) nanocrystals as used in a second embodiment of the present invention;

FIG. 6 is an external quantum efficiency spectra of a photovoltaic device according to the second embodiment of the present invention;

FIG. 7 illustrates a variation of open circuit voltage with nanocrystal band gap in the film according to the second embodiment of the present invention;

FIG. 8 illustrates device characteristics of a PbSe/pentacene device according to the second embodiment of the present invention; and

FIG. 9 illustrates, without being bound by theory; a description of the working principle of a PbSe/pentacene photovoltaic device according to the second embodiment of the present invention.

### DETAILED DESCRIPTION

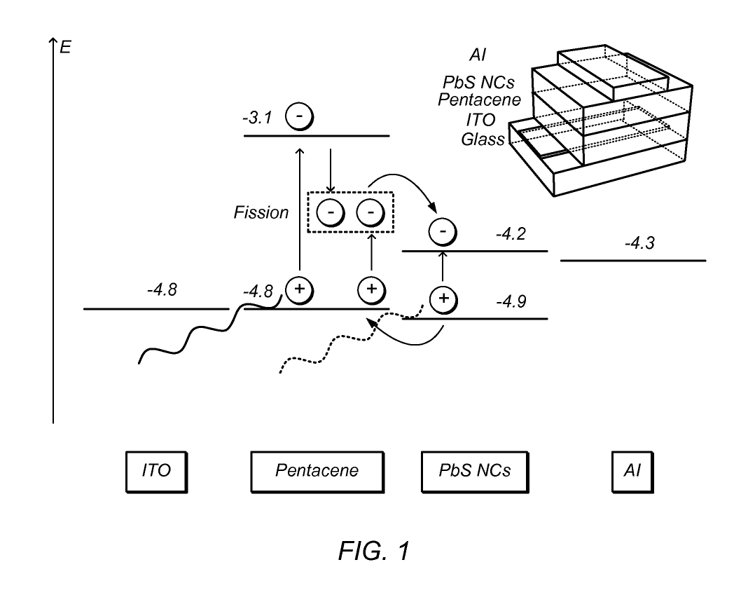

According to a first embodiment of the present invention we provide a device comprising infrared-absorbing lead sulfide (PbS) semiconductor nanocrystals as an electron acceptor, against which the pentacene triplet exciton is dissociated. PbS nanocrystals have proved successful in expanding power conversion into the infrared and offer the opportunity to tune the band gap due to quantum confinement. We tune the optical gap to 0.7 eV such that it is comparable to the pentacene triplet energy. As illustrated in FIG. 1, the resulting energy landscape at the interface allows hole transfer from the nanocrystals to the pentacene, while also favoring ionization of the pentacene triplet excitons via electron transfer to the PbS. Hybrid, bilayer devices were designed so that the light passes through the highenergy-gap pentacene first, as pentacene is transparent to the infrared photons that are absorbed by the nanocrystals.

Through this novel pairing of an organic material that undergoes fission and low-gap nanocrystals in a hybrid device architecture, it is possible to directly obtain photocurrent from infrared photons while harnessing the excess energy of visible photons to generate additional photocurrent.

### Example I

### Chemicals:

Lead(II) oxide (99.999%, PbO), oleic acid (technical grade, 90%, OA), 1-octadecene (technical grade, 90%, ODE), bis(trimethylsilyl)-sulfide (synthesis grade, TMS), hexane (anhydrous, 95%), ethanol (anhydrous, ≧99.5%), benzene-1,3-dithiol (≧99.0%, BDT), zinc acetate dihydrate (≧99.0%), methanol (dried, ≧99.9%), potassium hydroxide (99.99%, KOH), butylamine (99.5%), chloroform (anhydrous, ≧99%), and pentacene (triple-sublimed grade) were purchased from Sigma-Aldrichand used as received unless otherwise stated.

### PbS Nanocrystal Synthesis:

A three-neck flask was loaded with 0.47 g of PbO dissolved in 18 g of OA and 10 g of ODE and degassed at 100° C. in vacuum for three hours. The system was flushed with nitrogen and heated to 130° C. Separately, under a nitrogen atmosphere, 210 μL of TMS was dissolved in 4 mL of ODE (degassed in vacuum at 90° C. for 24 h) and loaded in a syringe. The content of the syringe was injected into the reaction flask and the heating was removed immediately. The system was subsequently left to cool to 35° C. The reaction was then quenched and the nanocrystals precipitated by the injection of a mixture of 2 mL of hexane (anhydrous) in 10 mL of ethanol (anhydrous). The nanocrystals were washed twice by dissolving in hexane and precipitating with ethanol. They were then stored in octane at a concentration of 100 mg/mL under a nitrogen atmosphere.

### Zinc Oxide Nanocrystal (ZnO) Synthesis:

A 0.9788 g of zinc acetate dihydrate was dissolved in 42 mL of methanol in a three-neck flask and heated to 60° C. under air. KOH (0.469 g) was dissolved in 22 mL of methanol and dropped into the reaction flask over a period of 10 min. After a total reaction time of about 90 min, the reaction solution turns pale. At this point, the heating was switched off and the flask was cooled to room temperature by blowing nitrogen at the reaction flask. The ZnO nanocrystals were precipitated by centrifuging briefly and then redispersed in 50 mL methanol and centrifuged twice to wash off unreacted material. Finally they were dissolved in chloroform and 75 μL of butylamine was added as a stabilizing ligand. The ZnO nanocrystals form a clear solution in chloroform.

### Device Fabrication:

ITO-coated glass slides were purchased from Psiotec and cleaned by sequential sonication in acetone and isopropanol followed by oxygen plasma treatment. All subsequent processing was performed in a nitrogen environment (˜1 ppm O₂). A 50 nm layer of pentacene was deposited onto the substrate via thermal evaporation at a rate of 0.1 Å/s under a vacuum of 2×10⁻⁶ mbar or better. This thickness balances the need to maximize optical absorption while ensuring excitons can diffuse to the heterojunction where they can be dissociated to yield photocurrent. The nanocrystals were then deposited using a layer-by-layer spin coating technique. All layers were spun for 15 s at 1500 rpm after a 3 s wait. First, a drop of BDT in anhydrous acetonitrile (0.23 vol %) was spun onto the pentacene surface. This was found to improve the film quality, presumably because it creates a layer of molecules that preferentially attach to the nanocrystals. Excess BDT that had not attached to the surface was washed off by spinning a layer of pure acetonitrile. PbS nanocrystals were dissolved in octane and spun immediately after filtration. After the deposition of each nanocrystal layer, a further layer of BDT in acetonitrile was spun to cross-link the nanocrystals followed by a layer of acetonitrile to wash off any unreacted BDT. This procedure was reproduced until the desired thickness was reached. Aluminum top contacts were thermally evaporated at a pressure of 3×10⁻⁶ mbar or better.

FIG. 1 shows the general structure of a typical device. The solar cells were encapsulated by affixing a glass slide on top of the completed device using transparent epoxy and taken out of the glovebox into the ambient environment for characterization. External quantum efficiencies were measured using monochromatic light from an Oriel Cornerstone 260 monochromator. The current-voltage measurement was carried out under an Oriel 92250A solar simulator with a Keithley 2636A source measure unit. The incident power was corrected for the spectral mismatch of the lamp used in the solar simulator over the spectral region from 375 to 1045 nm. We note that the solar cells tested here absorb light up to 1770 nm hence the correction for the spectral mismatch is not completely accurate. However, even in a worst-case scenario, this discrepancy is not expected to change the result by more than 4%.

### Optical Properties of PbS, ZnO, and Pentacene:

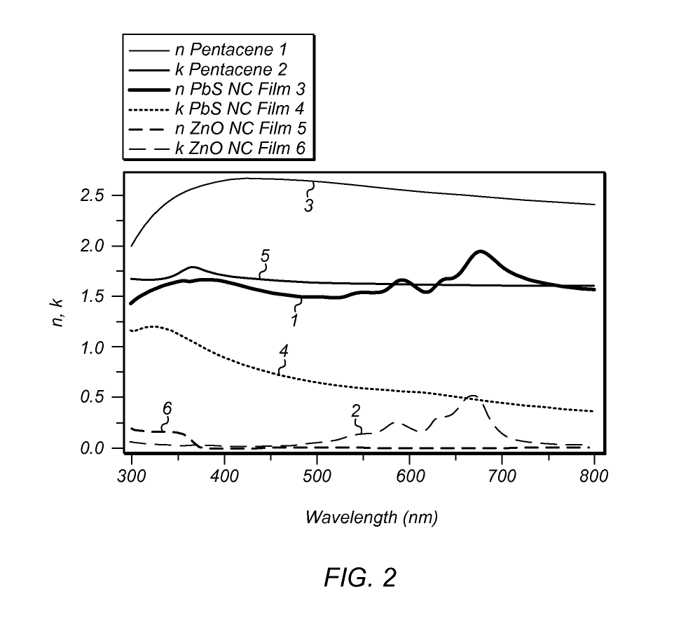

To perform variable-angle spectroscopic ellipsometry, films of PbS nanocrystals and ZnO nanocrystals were spin-coated on a silicon/silicon dioxide wafer and measured in reflection while the pentacene was evaporated onto a quartz-glass substrate and measured in transmission. The thicknesses were estimated using an atomic force microscope. The change in polarization of the incident light was measured with a J.A. Woollam variable angle spectroscopic ellipsometer. The data were fitted with a Cauchy model in the transparent region to find the thickness and then by a point-by-point model to extract the refractive index n and the extinction coefficient k over the whole wavelength range. The fit for the PbS nanocrystals was less accurate due to a lack of a transparent region so the extinction coefficient was calculated directly from the measured absorbance. The refractive index and the extinction coefficient for lead sulfide and zinc oxide nanocrystals as well as evaporated pentacene are shown in FIG. 2. The extinction coefficient of ZnO depends heavily on the crystallinity. Much larger values are reported for monocrystalline ZnO but our values are in good agreement with data reported for ZnO nanocrystals such as reported in Lakhwani, G.; Roijmans, R. F. H.; Kronemeijer, A. J.; Gilot, J.; Janssen, R. A. J.; Meskers, S. C. J. J. Phys. Chem. C 2010, 114, 14804-14810.

The optical field in the devices was modeled from the ellipsomery data using established procedures known to a person skilled in the art. With the extinction coefficient known, the fraction of light absorbed in each layer could be calculated as a function of the wavelength. The IQE was then determined by dividing the measured external quantum efficiency by the sum of the absorbed light fractions of the PbS layer and the pentacene layer.

### Results:

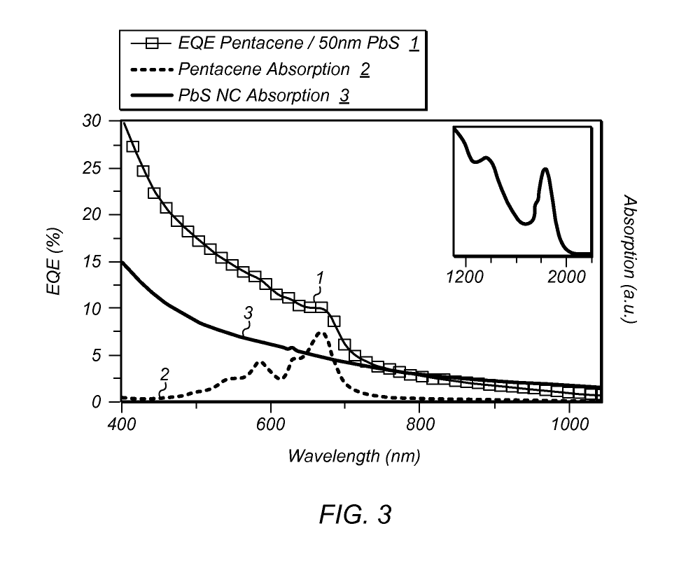

FIG. 3 shows the external quantum efficiency (EQE) of a hybrid bilayer solar cell with 50 nm layers of both pentacene and PbS nanocrystals. The shape of the EQE spectrum follows the absorption of the nanocrystals but shows a pronounced peak at 680 nm, implying an additional contribution from the absorption of pentacene. This shows that photocurrent is generated from both layers at the same time. Without being bound by theory, it is considered that photocurrent from pentacene stems from the ionization of pairs of triplets created by rapid singlet fission. Hence, the pentacene-sensitized, IR-absorbing solar cell presented here is the realization of a device that simultaneously absorbs low-energy photons and harnesses the excess energy of high-energy photons via singlet fission.

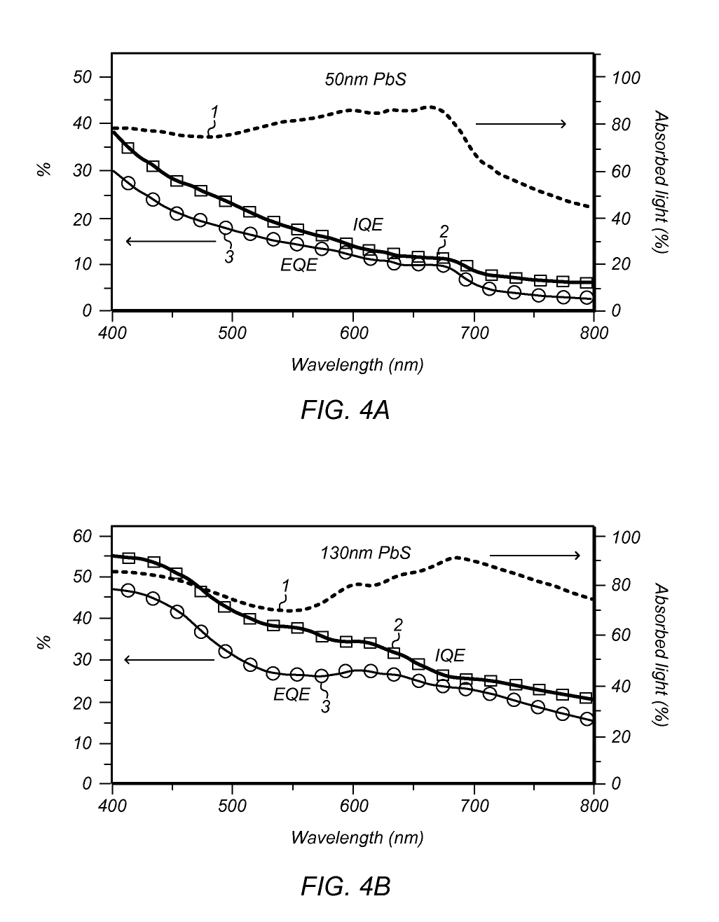

The IQE calculated from the optical modeling in the device with a thin (50 nm) PbS layer is presented in FIG. 4a. We find a small enhancement of the IQE in the region of the pentacene absorption. This is consistent with an increase in the yield of charges per photon due to exciton fission, but could also be explained without invoking exciton fission by a relative difference in the charge generation efficiencies of the individual layers.

Although the device with a thin layer of PbS nanocrystals most clearly showed the contribution from pentacene, the overall efficiency could be improved by increasing the thickness of the PbS layer. FIG. 4b presents the measured EQE and calculated IQE of a pentacene-sensitized device with a 130 nm P bS nanocrystal layer. This thickness was chosen using the optical modeling to predict the device architecture that would improve overall absorption while preserving a strong contribution from the pentacene in the EQE spectrum. We observed a substantial increase in the EQE of the device across the measured spectrum, which we attribute to the enhanced absorption as well as superior electrical properties arising from improved film formation. Additionally, while the relative contribution to the EQE from pentacene is decreased when compared to the thin device, a spectral signature consistent with the modeled two-layer absorption spectrum remains evident. However, the lack of an enhancement in the IQE in the region of strong pentacene absorption suggests the efficiency of collection of charges from triplet excitons in the pentacene is lower than that from nanoparticle excitons in the thicker cell. Further optimization is thus required to take full advantage of the additional excited states generated through the singlet fission process.

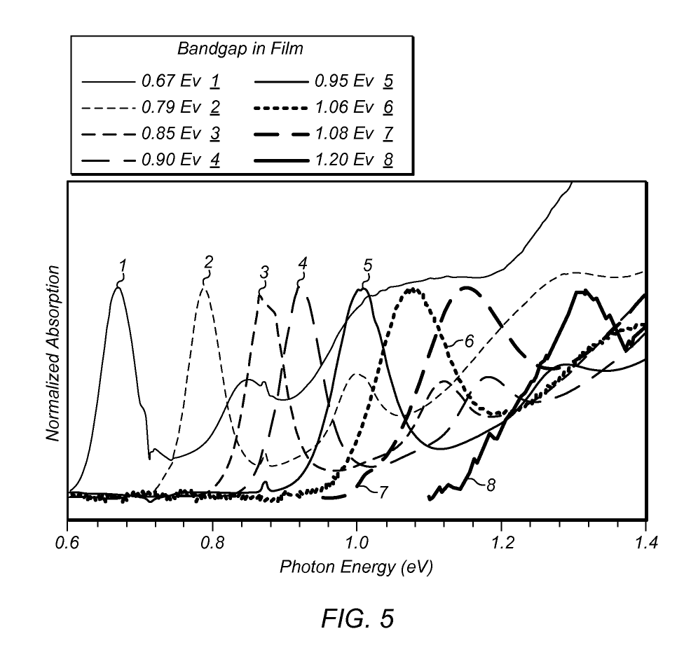

To further improve the performance of the device, we investigated the effect of adding a layer of zinc oxide (ZnO) nanocrystals between the PbS nanocrystals and the metallic top contact to improve charge extraction and to serve as an optical spacer. The thickness of this layer (100 nm) was again d etermined using optical modeling to beneficially redistribute the optical field in the device for absorption in the pentacene. As shown in FIG. 5, the addition of the ZnO layer increases the power conversion efficiencies under AM 1.5 solar illumination by a factor of 5, leading to a PCE of 0.85%. The device parameters are listed in Table 1.

TABLE 1
Device Parameters for the Solar Cells with a 130 nm Thick
PbS Layer with and without a Layer of ZnO Nanocrystals

| | | 100 nm ZnO |
|---|---|---|
| TABLE 1 | no ZnO | nanocrystals |
| Jsc (mA/cm2) | 4.86 | 7.61 |
| Voc (V) | 0.10 | 0.27 |
| FF | 33% | 41% |
| PCE | 0.16% | 0.85% |

The parameters are measured under AM1.5 G illumination at 1 sun. The spectral mismatch was taken into account as described in the experiment section.

We attribute the majority of the improvement in cell performance to an increase in charge extraction and the hole-blocking nature of the ZnO, since our modeling suggests that the incorporation of 100 nm ZnO only increases the overall light intensity absorbed by the cell by 5%.

In a second embodiment of the present invention, we fabricate photovoltaic cells with pentacene, using lead selenide (PbSe) nanocrystals as the infrared absorbing material. As for PbS, the bandgap of PbSe nanocrystals can be tuned over a wide range.

The absorption spectra of our PbSe nanocrystal size series is shown in FIG. 5. We synthesized nanocrystals using two different hot injection methods, and every sample in the size series was prepared using identical precursors to ensure all surfaces would be directly comparable. The nanocrystals exhibit polydispersities that are 3-5.7%. We also observed post-growth size focusing in our PbSe samples even after the reaction mixtures have been diluted and cooled to room temperature. The size series of nanocrystals was used after purification to make films for devices and analysis (see Example II below).

To determine the vacuum potentials of the lowest energy nanocrystal states, we investigated PbSe nanocrystal films atop pentacene via ultraviolet photoelectron spectroscopy (UPS, see Example II). The onset of the lowest energy ionization feature varies by only 0.03 eV over the nanocrystal size series (within measurement error of 0.05 eV) indicating that the size effect of the lowest (1Se-1S3/2) absorption is mostly due to changes in the confined conduction band state (1Se). We also found that the energy of the highest occupied molecular orbital in pentacene is −5.05±0.05 eV.

### Example II

### PbSe Nanocrystal Characterization:

The absorption spectra of the nanocrystals were taken using a PerkinElmer Lambda 9 UV-Vis-IR spectrometer.

### UPS/XPS Measurements:

The samples were transferred to the ultrahigh vacuum (UHV) chamber (ESCALAB 250Xi) for UPS/XPS measurements. UPS measurements were performed using a double-differentially pumped He gas discharge lamp emitting He I radiation (hᵥ=21.22 eV) with a pass energy of 2 eV. The UPS spectra are shown as a function of binding energy with respect to the vacuum level, and the low energy edge of the valence band is used to determine the ionization potential (IP) of the measured film. [A. Kahn, N. Koch, and W. Gao, J. Polym. Sci., Part B: Polym. Phys. 41, 2529 (2003)]

XPS measurements were carried out using a XR6 monochromated X-ray source with a 650 um spot size. Se3d spectra were normalized, so that the intensity of the Pb4f spectra represent the stoichiometry of the PbSe nanoparticles. The general trend shows that the smaller nanoparticles are richer in Pb.

The ionization potential of pentacene was measured to be 5.05 eV, in agreement with previous measurements by Koch et al [N. Koch, J. Ghijsen, R. L. Johnson, J. Schwartz, J.-J. Pireaux and A. Kahn, J. Phys. Chem. B 106, 4192 (2002)]. The FWHM of the valence band peak centred at −5.5 eV is 0.61 eV.

### Device Fabrication:

The devices were fabricated in a sequential bilayer structure. First, a 50 nm thick layer of pentacene was evaporated atop a pre-patterned ITO slide on glass (purchased from Psiotec). Pentacene was evaporated under a vacuum of <10-6 mbar at a rate of 0.1 Å/s. The samples were kept under inert atmosphere and the nanocrystals were spun in a glovebvox (<1 ppm O₂ and H₂O) in a sequential layer-by-layer technique as described above in connected with Example I. The nanocrystals were suspended in octane at 25 mg/mL and deposited through a 0.2 μm PTFE filter onto the substrate. After a 3 s wait the sample was spun at 1500 rpm for 10 s. To crosslink the nanocrystals, a 0.002M solution of 1,3-benzenedithiol (BDT) in acetonitrile was placed on the nanocrystals and was also spun after a 3 s wait at 1500 rpm. Residual BDT was washed off using pure acetonitrile, followed by one washing step with octane. This is considered as one layer. The number of layers determines the device thickness. The samples were transferred into a thermal evaporator without removing from the inert atmosphere. Lithium fluoride (LiF) and aluminum were deposited at 3×10-6 mbar or better. The devices were encapsulated by attaching a glass slide on top of the top contacts using a transparent epoxy.

The devices were characterized in air under an Oriel 92250A solar simulator using a Keithley 2636A source measure unit. The incident power was corrected for spectral mismatch in the spectral region from 375 nm to 1045 nm. Some of the solar cells were absorbing light with wavelengths above 1045 nm, the spectral mismatch factor however does not deviate by more than 4% for those cells. External quantum efficiency spectra were recorded under monochromatic light from an Oriel Cornerstone 260 monochromator.

To study the energy states of pentacene that are relevant to singlet fission, our photovoltaic devices were fabricated as follows. The pentacene and PbSe active layers were deposited in a bilayer structure on ITO such that incident light first passes through evaporated pentacene to absorb high energy photons. PbSe nanocrystals were spun cast on top of the pentacene via a layer-by-layer technique (see Example II). The top contacts consist of a thin layer of LiF and an aluminum electrode. By tuning the nanocrystal layer thickness to 50 nm in these devices, the visible light intensity is maximized in the pentacene layer.

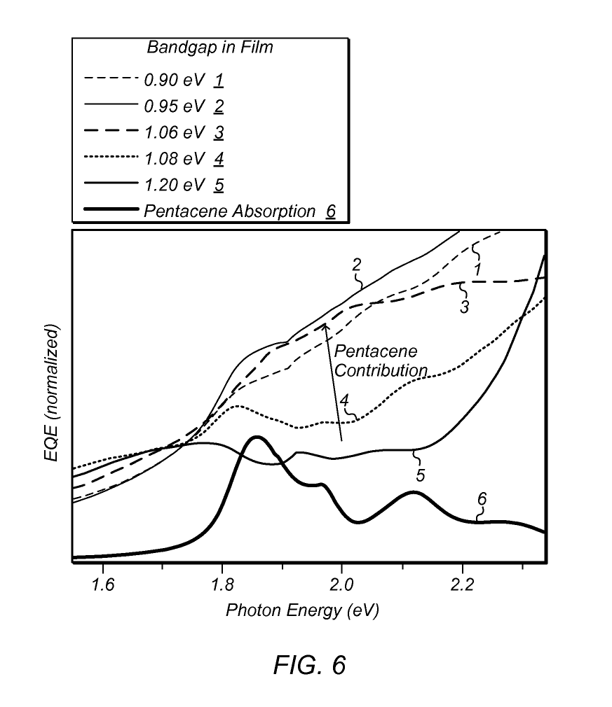

Photovoltaic devices made as above with a size series of PbSe nanocrystals have the external quantum efficiency (EQE) spectra shown in FIG. 6. The onset of photocurrent corresponds to the absorption onset of nanocrystals in the film, which occurs at a lower energy than the absorption of the same nanocrystals in solution. For the purposes of this discussion we identify the energy of the photocurrent onset as the band gap of the nanocrystals (Eg). The EQE spectra of devices made with the smallest band gap nanocrystals (0.67-1.05 eV) show a photocurrent contribution from pentacene. In the devices with 1.08 eV nanocrystals, pentacene contributes proportionally less photocurrent than PbSe. For devices with 1.2 eV nanocrystals, pentacene does not contribute to photocurrent and actually blocks light in its absorption band.

This threshold trend in the EQE spectra for the size series of PbSe devices has implications for the pentacene state that precedes charge generation. Following excitation of pentacene, the device operation combined with the appearance of the pentacene absorption features in the EQE spectrum indicates that there is charge separation across the PbSe/pentacene interface, resulting in net electron transfer to the nanocrystals. For the ensemble of nanocrystals there is a distribution of 1Se energies due to polydispersity in the nanocrystal size, and we approximate the standard deviation of the acceptor energy (σ) with the standard deviation of the 1Se-1S3/2 absorption feature. For devices containing nanocrystals with E_{g}=1.08 eV, the energy of the 1S3/2 state is −5.1±0.05 eV, and σ=0.057 eV.

Taken together these data suggest that the excitation in pentacene can be ionized at the interface with nanocrystals that have a 1Se state as high as −4.0±0.08 eV with respect to vacuum. As a result, we can estimate the energy limits of the excited state that precedes charge separation with PbSe. The UPS data indicate that the difference between the nanocrystal 1S3/2 state and the first ionization feature of pentacene is Δ=0.05±0.05 eV. There is evidently a suitable population of acceptor states to generate significant photocurrent from the device made with E_{g}=1.08 eV nanocrystals. To estimate a lower limit on the energy required to ionize the excited state of pentacene, we take the energy difference from the pentacene ionization energy to a point 2σ below the center of the nanocrystal 1Se distribution. Hence, the lower limit on the energy of the pentacene excited state is Eₜᵣₐₙₛ>E_{g}−Δ−2σ, or Eₜᵣₐₙₛ>0.92±0.11 eV.

The analogous results for the device with E_{g}=1.20 eV nanocrystals (which fails to ionize the triplet) can be used to estimate an upper limit on Eₜᵣₐₙₛ. For PbSe nanocrystals with E_{g}=1.20 eV, the standard deviation σ=0.061 eV and Δ=0.05±0.05 eV. Because the nanocrystal energy distribution does not have a sufficient fraction of states to act as acceptors for electron transfer from pentacene, we estimate that the bound state energy (Eₜᵣₐₙₛ) has limits such that Eₜᵣₐₙₛ<E_{g}−Δ+2σ, i.e. Eₜᵣₐₙₛ<1.27±0.13 eV.

The above results are independent of optical modeling or specific knowledge about the electronic structure of pentacene. However it is important to note that from photocurrent, photoelectron spectroscopy, and steady state absorption data, we identify a state whose energy matches that of a triplet that was imprecisely observed in pentacene previously. That Etrans is equal (to within error) of one-half of the energy of the pentacene S1 state suggests that the activation energy for singlet fission is low

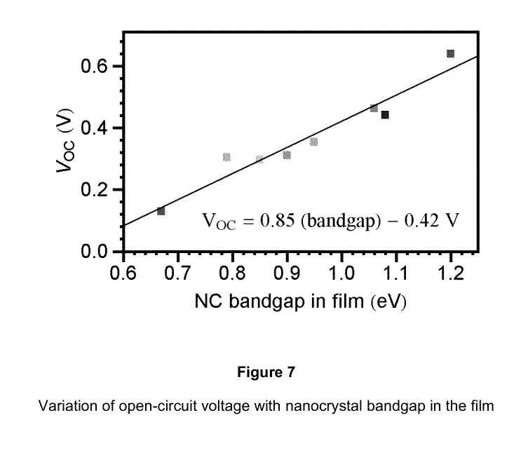

We also studied the photovoltaic performance of the PbSe/pentacene devices. Current-voltage characteristics demonstrate that all devices exhibit qualitatively similar Ohmic device behavior. The change of the open circuit voltage (Voc) varies with nanocrystal band gap, as shown explicitly in FIG. 7. An alternative processing method was used for the 1.06 and 1.20 eV nanocrystals and lead to the reduced short circuit current for these devices (see Example II). A linear fit of the V_{oc} vs. nanocrystal band gap has a slope of 0.83, indicating that the change in V_{oc} is correlated with the nanocrystal size and consistent with the finding that the 1S3/2 state is largely constant across the size series.

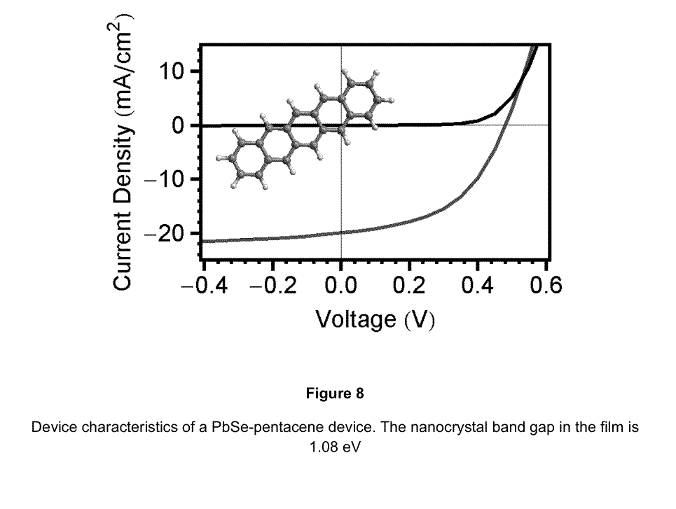

The variation between nanocrystal band gap (E_{g}) and V_{oc} provides a useful design motif by which to optimize devices. To preserve the advantage of the additional current from pentacene, the solar cells should be designed with E_{g} as large as possible while preserving the triplet ionization capability. Additionally, studies on variable nanocrystal layer thickness showed that our devices performed best for a PbSe layer thickness of 150 nm. We show the IV characteristic and relevant parameters for a device (4.7% PCE) in FIG. 8.

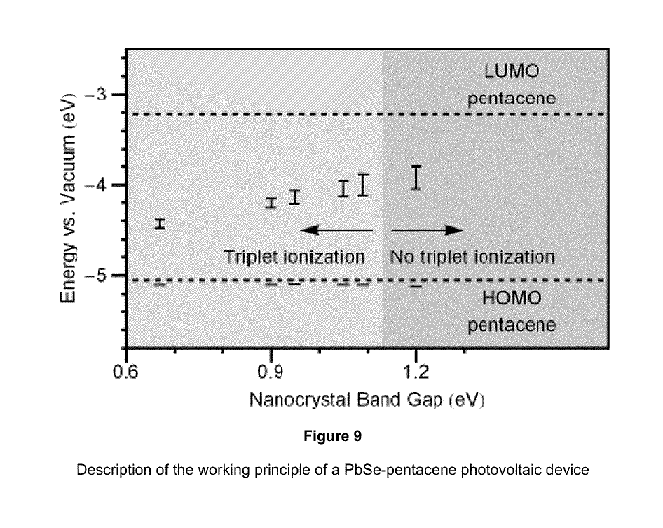

In conclusion, we have fabricated photovoltaic devices with a size series of PbSe nanocrystals and pentacene. Using the nanocrystal size series as electron acceptors with tunable energy, we find that the excited state leading to charge separation has an energy Eₜᵣₐₙₛ above the ground state, with 0.92±0.11<Eₜᵣₐₙₛ<1.27±0.13 eV (FIG. 9).

Although the embodiments above have been described in considerable detail, numerous variations and modifications will become apparent to those skilled in the art once the above disclosure is fully appreciated. It is intended that the following claims be interpreted to embrace all such variations and modifications.

We claim:

1. A method of fabricating a photovoltaic device, the method comprising:
depositing an organic semiconductor layer over a first electrode;
depositing a cross-linking ligand layer over the organic semiconductor layer;
depositing, over the cross-linking ligand layer, an inorganic nanocrystal layer comprising lead chalcogenide nanocrystals; and
depositing a second electrode over the inorganic nanocrystal layer.

2. The method as claimed in claim 1, wherein the lead chalcogenide nanocrystals are lead selenide or lead sulfide.

3. The method as claimed in claim 1, further comprising:
depositing one or more additional layers over the inorganic nanocrystal layer, wherein the one or more additional layers includes another cross-linking ligand layer; and
depositing another inorganic nanocrystal layer over the other cross-linking ligand layer.

4. The method as claimed in claim 1, further comprising:
depositing one or more additional inorganic nanocrystal layers over the inorganic nanocrystal layer.

5. The method as claimed in claim 4, wherein the one or more additional inorganic nanocrystal layers comprise lead chalcogenide nanocrystals.

6. The method as claimed in claim 4, wherein the one or more additional inorganic nanocrystal layers comprise one or more nanocrystals that include CdSe, CDS, ZnTe, ZnSe. PbS, PbSe, PbTe, HgS, HgSe, HgTe, HgCdTe, CdTe, CZTS, ZnS, CuInS2, CuInGaSe, CuInGaS, Si, InAs, InP, InSb, SnS2, CuS, or Fe2S3.

7. The method as claimed in claim 1, wherein the depositing the inorganic nanocrystal layer includes spin-coating, spray coating, inkjet printing, dip coating, spray pyrolysis, or screen printing.

8. The method as claimed in claim 1, wherein the organic semiconductor layer comprises a polyacene.

9. The method as claimed in claim 8, wherein the polyacene is pentacene.

10. The method as claimed in claim 1, wherein the cross-linking ligand layer comprises benzenedithiol.

11. The method as claimed in claim 1, further comprising:
imprinting the organic semiconductor layer prior to the depositing the cross-linking ligand layer over the organic semiconductor layer.

12. The method as claimed in claim 1, wherein the first electrode is an anode and the second electrode is a cathode.

13. A photovoltaic device comprising:
a first electrode;
a second electrode;
an organic semiconductor layer disposed between the first electrode and the second electrode; and
at least one cross-linked inorganic nanocrystal layer disposed over the organic semiconductor layer, wherein the at least one cross-linked inorganic nanocrystal layer comprises lead chalcogenide nanocrystals.

14. The photovoltaic device as claimed in claim 13, wherein the lead chalcogenide nanocrystals are lead selenide or lead sulfide.

15. The photovoltaic device as claimed in claim 13, wherein the at least one cross-linked inorganic nanocrystal layer includes a cross-linked ligand layer comprising benzenedithiol.

16. The photovoltaic device as claimed in claim 13, wherein the first electrode is an anode, and wherein the organic semiconductor layer is deposited on the anode.

17. The photovoltaic device as claimed in claim 13, wherein the organic semiconductor layer is a polyacence.

18. The photovoltaic device as claimed in claim 13, further comprising:
one or more additional layers disposed over the inorganic nanocrystal layer, wherein the one or more additional layers comprise another one or more benzenedithiol cross-linked inorganic nanocrystal layer.

19. The photovoltaic device as claimed in claim 13, further comprising:
one or more additional layers disposed over the inorganic nanocrystal layer, wherein the one or more additional layers comprise another inorganic nanocrystal layer.

20. The photovoltaic device as claimed in claim 19, wherein the other inorganic nanocrystal layer comprises lead chalcogenide nanocrystals.

21. The photovoltaic device as claimed in claim 19, wherein the other inorganic nanocrystal layer comprises CdSe, CDS, ZnTe, ZnSe, PbS, PbSe, PbTe, HgS, HgSe, HgTe, HgCdTe, CdTe, CZTS, ZnS, CuInS2, CuInGaSe, CuInGaS, Si, InAs, InP, InSb, SnS2, CuS, or Fe2S3.

22. A solar cell comprising an array of photovoltaic devices, wherein at least one of the photovoltaic devices comprises:
a first electrode;
a second electrode;
an organic semiconductor layer disposed between the first electrode and the second electrode; and
at least one cross-linked inorganic nanocrystal layer disposed over the organic semiconductor layer, wherein the at least one cross-linked inorganic nanocrystal layer comprises lead chalcogenide nanocrystals.
